(19) United States
(12) Patent Application Publication
(10) Pub. No.: US 2026/0266914 A1
(43) Pub. Date: Sep. 10, 2026

(54) SECONDARY BATTERY TEST APPARATUS AND METHOD

(71) Applicant: SK On Co., Ltd., Seoul (KR)

(72) Inventors: Seung Won CHOI, Daejeon (KR); Won Je OH, Daejeon (KR); Moon Hyung JUNG, Daejeon (KR); Hak Bong MUN, Daejeon (KR); Ki Sang YOO, Daejeon (KR)

(21) Appl. No.: 19/554,663

(22) Filed: Mar. 3, 2026

(30) Foreign Application Priority Data
Mar. 5, 2025 (KR) 10-2025-0027854

(51) Int. Cl. G01R 31/385; G01R 31/36; G01R 31/378; G01R 31/389

(52) U.S. Cl. CPC G01R 31/385; G01R 31/3644; G01R 31/378; G01R 31/389

(57) ABSTRACT

A secondary battery test apparatus and method are disclosed. The secondary battery test apparatus includes a pressing sheet disposed on an outer circumferential surface of an electrode assembly, wherein the pressing sheet is provided as a flexible sheet configured to wrap around the outer circumferential surface, and is configured to press the outer circumferential surface toward the central axis of the electrode assembly in tight surface contact with the outer circumferential surface according to external force acting in a longitudinal direction.

### CROSS-REFERENCE TO RELATED APPLICATION

This application claims the benefit of priority to Korean Patent Application No. 10-2025-0027854 filed on Mar. 5, 2025, the disclosure of which is incorporated herein by reference in its entirety.

### TECHNICAL FIELD

Embodiments of the present disclosure relate to a secondary battery test apparatus and method.

### BACKGROUND

A secondary battery is an energy storage means capable of being charged and discharged through electrochemical reaction. Secondary batteries are used in various fields using electrical energy. For example, secondary batteries are widely used in mobile devices such as mobile phones, laptop computers, and tablet computers, and broader utilization thereof is being pursued in transportation equipment such as vehicles, aircraft, and ships. In addition, demand for secondary batteries is increasing in the energy storage system (ESS) field for utilizing surplus power.

A secondary battery may be configured such that positive electrodes and negative electrodes are alternately and repeatedly disposed in the state in which separators are interposed therebetween. For example, for a cylindrical battery, positive electrodes and negative electrodes alternately and repeatedly disposed with separators interposed therebetween may be wound in a cylindrical shape to form an electrode assembly, and the electrode assembly may be received in a case. The secondary battery may be processed through a plurality of process steps, and external force applied during each step, various byproducts generated during processing, and foreign matter introduced from an external environment may cause defects in the manufactured secondary battery. For example, various byproducts generated during processing may be introduced into the electrode assembly, damaging the separators or causing electrical short circuit. Consequently, it is necessary to determine whether the manufactured secondary battery is defective through measurement of leakage current, etc.

### SUMMARY

Some embodiments of the present disclosure may provide a secondary battery test apparatus and method.

In addition, some embodiments of the present disclosure may provide a secondary battery test apparatus and method capable of appropriately determining whether a secondary battery has processing defects.

In addition, some embodiments of the present disclosure may provide a secondary battery test apparatus and method capable of being appropriately utilized for cylindrical electrode assemblies.

In addition, some embodiments of the present disclosure may provide a secondary battery test apparatus and method capable of improving the reliability of test results.

Some embodiments of the present disclosure may be widely adopted in green technology fields such as electric vehicles, battery charging stations, and other battery-utilizing applications like solar power generation and wind power generation. In addition, some embodiments of the present disclosure may be used in eco-friendly electric vehicles (EVs) and hybrid vehicles (HVs) to prevent climate change by suppressing air pollution and greenhouse gas emissions.

According to an aspect of the present disclosure, a secondary battery test apparatus includes a pressing sheet disposed on an outer circumferential surface of an electrode assembly, wherein the pressing sheet is provided as a flexible sheet configured to wrap around the outer circumferential surface, and is configured to press the outer circumferential surface toward a central axis of the electrode assembly in tight surface contact with the outer circumferential surface according to external force acting in a longitudinal direction.

In some embodiments, the electrode assembly may be configured such that positive electrodes and negative electrodes alternately and repeatedly disposed with separators interposed therebetween are wound around the central axis in a cylindrical shape.

In some embodiments, the secondary battery test apparatus may include a measurement device configured to measure at least one of leakage current and insulation resistance of the electrode assembly in the state in which the pressing sheet appropriately presses the outer circumferential surface.

In some embodiments, the pressing sheet may include an electrically insulating material.

In some embodiments, the pressing sheet may include a first sheet region extending from a first end thereof in the longitudinal direction and a second sheet region extending from an end of the first sheet region to a second end corresponding to the first end in the longitudinal direction.

In some embodiments, the first sheet region may include at least one slit, and the second sheet region may be inserted into and fastened to the slit so as to be movable in the longitudinal direction.

In some embodiments, the first sheet region may have a first width, and the second sheet region may have a second width less than the first width.

In some embodiments, the second width may be equal to or greater to a predetermined extent than the height of the electrode assembly.

In some embodiments, the pressing sheet may be configured such that external force is applied to a first end thereof in a first direction and external force is applied to a second end thereof corresponding to the first end in a second direction opposite the first direction to press the outer circumferential surface.

In some embodiments, the pressing sheet may include a first pressing sheet configured to wrap around a part of the outer circumferential surface in a first rotational direction and a second pressing sheet configured to wrap around another part of the outer circumferential surface in a second rotational direction opposite the first rotational direction.

In some embodiments, each of the first and second pressing sheets may be provided in plural, and the pluralities of first and second pressing sheets may be alternately and repeatedly disposed in a height direction of the electrode assembly.

In some embodiments, external force may be applied to the first pressing sheet in a direction corresponding to the first rotational direction such that the first pressing sheet presses the part of the outer circumferential surface, and external force may be applied to the second pressing sheet in a direction corresponding to the second rotational direction such that the second pressing sheet presses the other part of the outer circumferential surface.

In some embodiments, the secondary battery test apparatus may include a bracket configured to support a first end of each of the first and second pressing sheets, wherein the bracket may include a first slit configured to allow a second end of the first pressing sheet to be inserted thereinto and fastened thereto so as to be movable in the longitudinal direction and a second slit configured to allow a second end of the second pressing sheet to be inserted thereinto and fastened thereto so as to be movable in the longitudinal direction.

According to another aspect of the present disclosure, a secondary battery test method includes disposing a pressing sheet provided as a flexible sheet on an outer circumferential surface of an electrode assembly, applying external force to the pressing sheet such that the pressing sheet presses the outer circumferential surface in tight surface contact with the outer circumferential surface, and measuring at least one of leakage current and insulation resistance of the electrode assembly in the pressed state.

In some embodiments, the secondary battery test method may include releasing the external force and separating the electrode assembly from the pressing sheet upon completion of the measurement step.

### BRIEF DESCRIPTION OF THE DRAWINGS

FIG. 1 is an illustrative view showing an electrode assembly of a secondary battery;

FIG. 2 is a schematic perspective view showing a test apparatus according to an embodiment of the present disclosure;

FIG. 3 is a development view of the test apparatus shown in FIG. 2;

FIG. 4 is a plan view of the test apparatus shown in FIG. 2;

FIG. 5 is a front view of the test apparatus shown in FIG. 2;

FIG. 6 is a schematic perspective view showing a test apparatus according to another embodiment of the present disclosure;

FIG. 7 is a development view of the test apparatus shown in FIG. 6;

FIG. 8 is a flowchart showing a test method according to an embodiment of the present disclosure; and

FIG. 9 is a schematic view showing the state of an electrode assembly according to a pressing step in FIG. 8.

### DETAILED DESCRIPTION

Hereinafter, the present disclosure will be described in detail with reference to the accompanying drawings. However, this is merely illustrative, and the present disclosure is not limited to specific embodiments described by way of example.

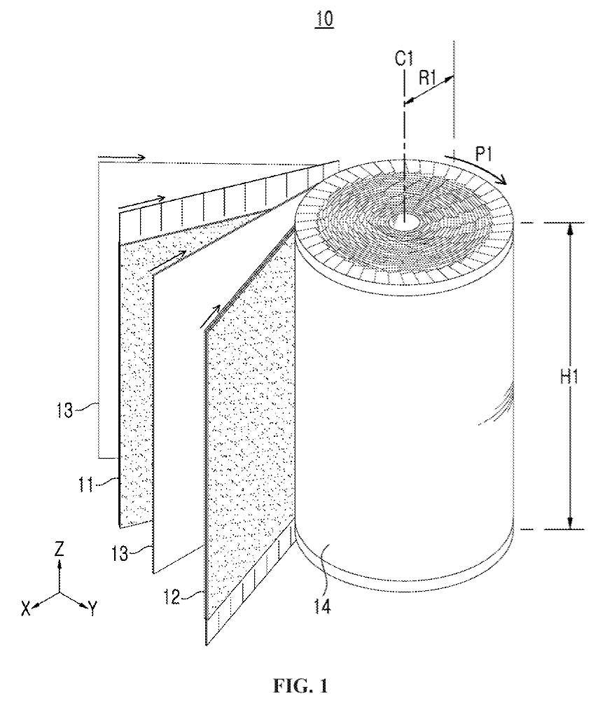

FIG. 1 is an illustrative view showing an electrode assembly of a secondary battery.

FIG. 1 illustrates an electrode assembly 10 of a secondary battery. In some embodiments, the electrode assembly 10 may be configured in a cylindrical shape. Specifically, the electrode assembly 10 may be configured such that positive electrodes 11 and negative electrodes 12 alternately and repeatedly disposed with separators 13 interposed therebetween are wound around a central axis C1 in a cylindrical shape. For reference, in the shown embodiment, the central axis C1 is illustrated as an axis in a z-axis direction. In addition, the separators 13, the positive electrodes 11, and the negative electrodes 12 are wound in a circumferential direction P1 centered on the central axis C1 to form a cylindrical electrode assembly 10.

In some embodiments, a secondary battery test apparatus (hereinafter referred to as a “test apparatus 100”), described below, may be applied to the illustrated cylindrical electrode assembly 10. In other words, the test apparatus 100 may be appropriately used to measure leakage current, etc., of the cylindrical electrode assembly 10. In addition, the test apparatus 100 may be configured to apply uniform pressure to an outer circumferential surface 14 of the cylindrical electrode assembly 10 and to measure leakage current, etc., in the state in which the electrode assembly 10 is thus pressed. In some embodiments, the test apparatus 100 may function to more accurately determine whether the cylindrical electrode assembly 10 has processing defects. For example, the test apparatus 100 may amplify the influence of foreign matter through appropriate pressing and measure leakage current, etc., to more accurately determine whether the cylindrical electrode assembly 10 has processing defects in this state.

However, the application of the test apparatus 100 is not necessarily limited to the illustrated cylindrical electrode assembly 10. The test apparatus 100 may also be applied to electrode assemblies 10 of shapes different from the illustrated shape provided the test apparatus appropriately incorporates the technical concepts described below.

Meanwhile, the cylindrical electrode assembly 10 may have a predetermined radius R1 and height H1 centered on the central axis C1. In the shown embodiment, the radius R1 of the electrode assembly 10 may refer to the length on an xy plane extending from the central axis C1 to the outer circumferential surface 14 of the electrode assembly 10. In addition, the height H1 of the electrode assembly 10 may refer to the length of the electrode assembly 10 in the z-axis direction. In the present disclosure, the radius R1 and height H1 of the electrode assembly 10 to which the test apparatus 100 is applied are not particularly limited. Furthermore, in some embodiments, the test apparatus 100 may be configured to be applicable to electrode assemblies 10 having different specifications. In other words, the test apparatus 100 may be configured to be compatible with each electrode assembly 10 having a somewhat different radius R1 and/or height H1. The test apparatus 100 may contribute to enhancing the ease of use or operational efficiency of equipment.

In some embodiments, the cylindrical electrode assembly 10 may have an outer circumferential surface 14. In the shown embodiment, the outer circumferential surface 14 may refer to the circumference of a side surface of the electrode assembly 10. The outer circumferential surface 14 may extend with a predetermined curvature centered on the central axis C1.

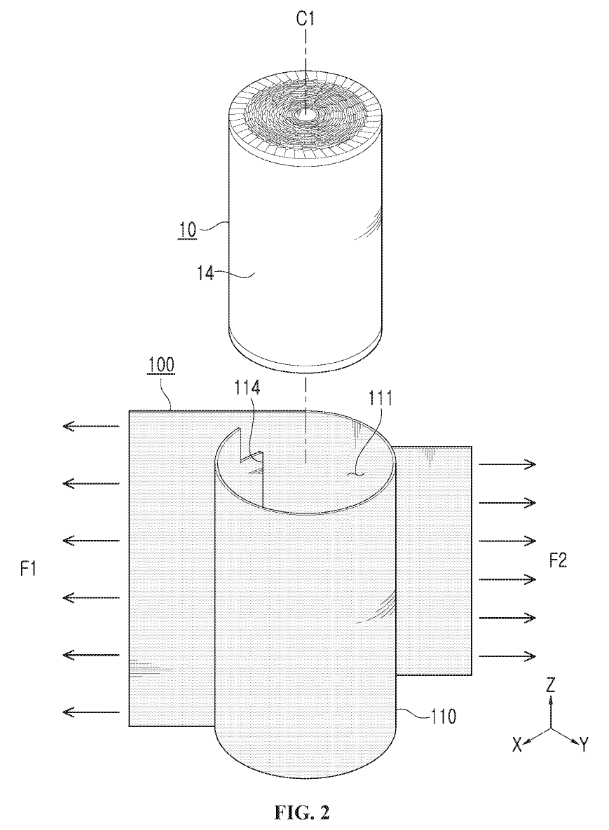

FIG. 2 is a schematic perspective view showing a test apparatus according to an embodiment of the present disclosure.

Referring to FIG. 2, in some embodiments, a test apparatus 100 may be provided. The test apparatus 100 may be used to measure leakage current, etc., of the electrode assembly 10. In some embodiments, the test apparatus 100 may include a pressing sheet 110 disposed on the outer circumferential surface 14 of the electrode assembly 10. Here, the pressing sheet 110 is provided as a flexible sheet configured to wrap around the outer circumferential surface 14, and may be configured to press the outer circumferential surface 14 toward the central axis C1 of the electrode assembly 10 in tight surface contact with the outer circumferential surface 14 according to external forces F1 and F2 acting in a longitudinal direction.

Specifically, the pressing sheet 110 may be disposed so as to wrap around the outer circumferential surface 14 of the electrode assembly 10. In the shown embodiment, the pressing sheet 110 may form an approximately cylindrical mounting space 111, and the electrode assembly 10 may be disposed in the mounting space 111.

In some embodiments, the pressing sheet 110 may be made of a flexible material capable of wrapping around the outer circumferential surface 14 of the electrode assembly 10. In addition, the pressing sheet 110 may be provided as a sheet member having a predetermined thickness. The pressing sheet 110 provided as such a flexible sheet may function to uniformly apply pressure to the outer circumferential surface 14 of the electrode assembly 10. Accordingly, the influence of internal foreign matter during the measurement of leakage current, etc. may be appropriately amplified, whereby it is possible to more clearly determine whether the electrode assembly has processing defects. In addition, the pressing sheet 110 provided as a flexible sheet may contribute to facilitating adaptation to the specifications of the electrode assembly 10. That is, the pressing sheet 110 provided as a flexible sheet may be relatively easily compatible with electrode assemblies 10 of various specifications.

In some embodiments, the pressing sheet 110 may include an electrically insulating material. That is, the pressing sheet 110 may be made partially or entirely of an electrically insulating material so as to be electrically insulated from the electrode assembly 10. The electrically insulating material forming the pressing sheet 110 is not particularly limited, provided the electrically insulating material has predetermined flexibility and can be formed into a sheet shape. For example, the pressing sheet 110 may be made partially or entirely of a synthetic resin.

Meanwhile, in some embodiments, the pressing sheet 110 may be configured to press the outer circumferential surface 14 of the electrode assembly 10. Specifically, external forces F1 and F2 may be applied to the pressing sheet 110. In the shown embodiment, the external forces F1 and F2 may be applied to pull longitudinal ends of the pressing sheet 110 in opposite directions. Accordingly, the pressing sheet 110 may be brought into tight surface contact with the outer circumferential surface 14 of the electrode assembly 10. In addition, the pressing sheet 110 may be operated to apply a predetermined degree of pressure to the outer circumferential surface 14 of the electrode assembly 10 toward the center axis C1. The test apparatus 100 may be configured to measure leakage current, etc., in the state in which the electrode assembly 10 is pressed in this manner.

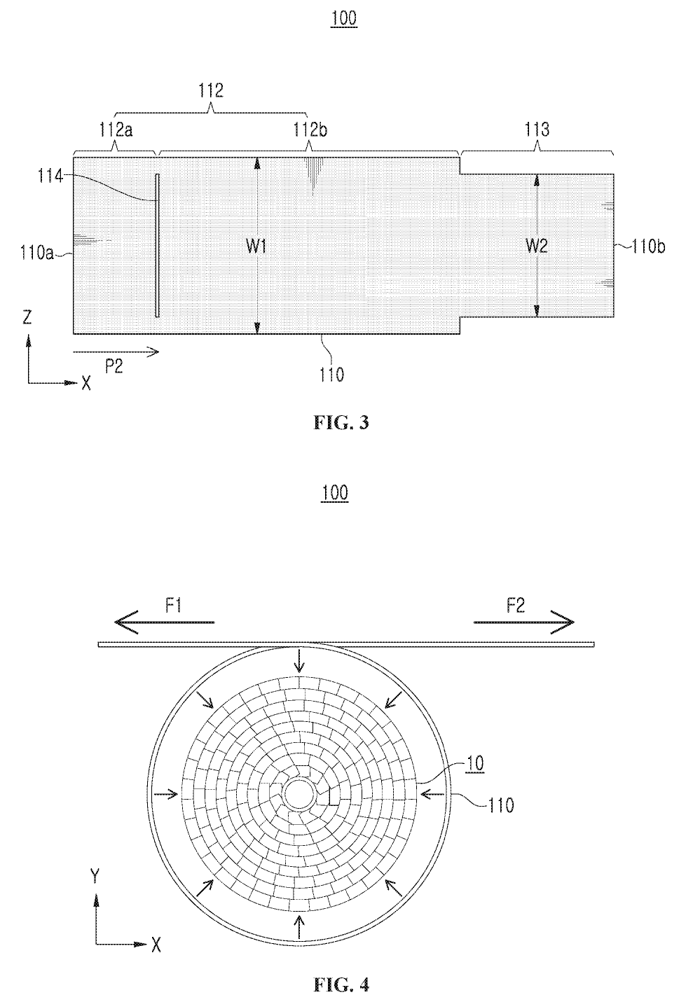

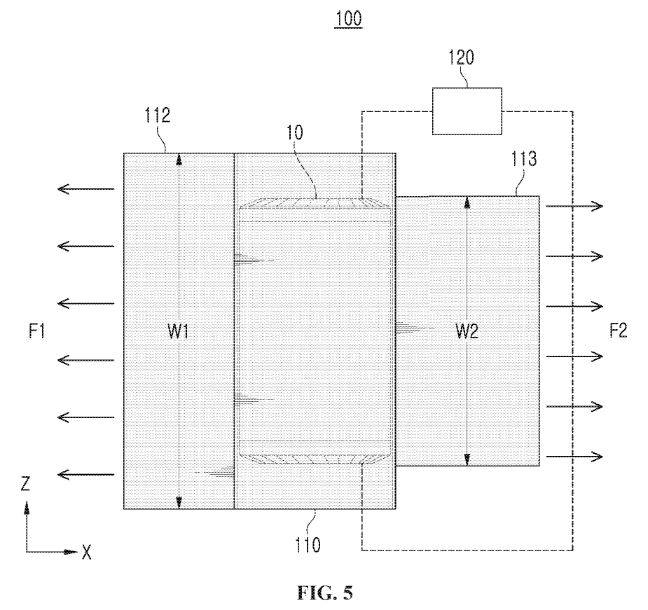

FIG. 3 is a development view of the test apparatus shown in FIG. 2. FIG. 4 is a plan view of the test apparatus shown in FIG. 2. FIG. 5 is a front view of the test apparatus shown in FIG. 2.

Referring to FIGS. 3 to 5, in some embodiments, the pressing sheet 110 may include a first sheet region 112 and a second sheet region 113. The first sheet region 112 may extend from a first end 110a of the pressing sheet 110 in a longitudinal direction P2. For reference, the longitudinal direction P2 may refer to a direction in which the pressing sheet 110 is wrapped around the outer circumferential surface 14 of the electrode assembly 10. In the development view of FIG. 3, the longitudinal direction P2 corresponds to an x-axis direction. In addition, the first end 110a may refer to one end of the pressing sheet 110 in the longitudinal direction P2. In the development view of FIG. 3, the first end 110a corresponds to a left end of the pressing sheet 110 in the x-axis direction.

The second sheet region 113 may extend from an end of the first sheet region 112 to a second end 110b in the longitudinal direction P2. The second end 110b may refer to the opposite end corresponding to the first end 110a. In the development view of FIG. 3, the second end 110b corresponds to a right end of the pressing sheet 110 in the x-axis direction. Furthermore, in the development view of FIG. 3, the second sheet region 113 may extend from a right end of the first sheet region 112 to the second end 110b in the longitudinal direction P2.

In some embodiments, the first and second sheet regions 112 and 113 may be formed with a sufficiently long length to completely wrap around the outer circumferential surface 14 of the electrode assembly 10. That is, the total length of the first and second sheet regions 112 and 113 in the longitudinal direction P2 may be formed sufficiently greater than the length along the outer circumferential surface 14 of the electrode assembly 10. The first and second sheet regions 112 and 113 may contribute to enabling the application of the test apparatus 100 to electrode assemblies 10 of different specifications.

In some embodiments, the first sheet region 112 may have a first width W1. For reference, the first width W1 may refer to the width of the first sheet region 112 in a direction perpendicular to the longitudinal direction P2. In the shown embodiment, the first width W1 corresponds to the width of the first sheet region 112 in the z-axis direction. Meanwhile, the second sheet region 113 may have a second width W2. The second width W2 may refer to the width of the second sheet region 113 in a direction perpendicular to the longitudinal direction P2. In the shown embodiment, the second width W2 corresponds to the width of the second sheet region 113 in the z-axis direction.

In the above, the second width W2 may be less than the first width W1. In other words, the second sheet region 113 may have a width less to a predetermined extent than the width of the first sheet region 112. In addition, the second width W2 may be equal to the height H1 of the electrode assembly 10 or may be greater to a predetermined extent than the height H1 of the electrode assembly 10. The second width W2 may enable the pressing sheet 110 to completely wrap around the outer circumferential surface 14 of the electrode assembly 10 in a height direction and ensure that the pressure applied by the pressing sheet 110 acts uniformly across the entire outer circumferential surface 14 of the electrode assembly 10. In addition, the second width W2 may enable the test apparatus 100 to be applied to electrode assemblies 10 of different specifications.

Meanwhile, in some embodiments, the first sheet region 112 may have a slit 114. The slit 114 may be provided by partially cutting the first sheet region 112. In addition, the slit 114 may be disposed on one side of the first sheet region 112 in the longitudinal direction P2 and extend in a width direction of the first sheet region 112. In the shown embodiment, the slit 114 is disposed adjacent to the left end of the first sheet region 112 in the x-axis direction and extends a predetermined length in the z-axis direction.

The slit 114 may be fastened to the second sheet region 113. That is, the second end 110b of the second sheet region 113 may be inserted into and fastened to the slit 114, and may be movable in the longitudinal direction P2 in a state of being inserted into the slit 114. Through such movement of the second sheet region 113, the pressing sheet 110 may appropriately press the electrode assembly 10 disposed in the mounting space 111. Meanwhile, for appropriate coupling to the second sheet region 113, the width of the slit 114 may correspond to the second width W2 or may be greater to a predetermined extent than the second width W2.

In some embodiments, the first sheet region 112 may be divided into a 1-1 sheet region 112a and a 1-2 sheet region 112b centered around the slit 114. In FIG. 3, the 1-1 sheet region 112a corresponds to a part of the first sheet region 112 disposed on a left side of the slit 114, and the 1-2 sheet region 112b corresponds to a part of the first sheet region 112 disposed on a right side of the slit 114. In some embodiments, at least a part of the 1-1 sheet region 112a may be disposed spaced apart from the outer circumferential surface 14 of the electrode assembly 10 such that external forces F1 and F2 for testing can be applied to the 1-1 sheet region (see FIG. 4). In addition, at least a part of the 1-2 sheet region 112b may be disposed on the outer circumferential surface 14 of the electrode assembly 10 in tight contact therewith such that the 1-2 sheet region can press the outer circumferential surface 14 toward the central axis C1 (see FIG. 4).

Meanwhile, the pressing sheet 110 may be operated to press the outer circumferential surface 14 of the electrode assembly 10. In some embodiments, opposing external forces F1 and F2 may be applied to both ends 110a and 110b of the pressing sheet 110 such that the pressing sheet can press the outer circumferential surface 14 of the electrode assembly 10. For example, in FIG. 4, external force F1 may be applied to the left end, i.e., the first end 110a, in a first direction (a leftward direction), and external force F2 may be applied to the right end, i.e., the second end 110b, in a second direction (a rightward direction). Accordingly, the pressing sheet 110 may be operated to press the outer circumferential surface 14 of the electrode assembly 10 while the inner diameter thereof decreases.

In the above, the pressing sheet 110 may be operated to press the outer circumferential surface 14 of the electrode assembly 10 in uniform contact with the entirety of the outer circumferential surface 14 of the electrode assembly 10. That is, the pressing sheet 110 may be operated to uniformly press the outer circumferential surface 14 of the electrode assembly 10 toward the central axis C1 in surface contact with the entirety of the outer circumferential surface 14 of the electrode assembly 10. Accordingly, when measuring leakage current, etc. in a subsequent step, the influence of internal foreign matter may be appropriately amplified, and whether the electrode assembly 10 is defective may be more clearly determined.

In some embodiments, the external forces F1 and F2 applied to both ends 110a and 110b of the pressing sheet 110 may be equal. Furthermore, in some embodiments, any one of the external forces F1 and F2 applied to both ends 110a and 110b of the pressing sheet 110 may be reaction force. For example, the first end 110a of the pressing sheet 110 may be fixed, and the external force F2 may be applied to the second end 110b of the pressing sheet 110 to press the electrode assembly 10. Here, the external force F1 applied to the first end 110a may be reaction force caused by the external force F2 applied to the second end 110b.

Meanwhile, in some embodiments, the test apparatus 100 may further include a measurement device 120. For reference, the measurement device 120 is briefly shown in FIG. 5 and omitted from other figures for convenience. The measurement device 120 may be configured to detect whether the electrode assembly 10 has an insulation defect in the state in which the pressing sheet 110 appropriately presses the outer circumferential surface 14. For example, the measurement device 120 may be connected to the electrodes 11 and 12 of the electrode assembly 10 to measure leakage current and/or insulation resistance. In addition, the measurement device 120 may detect whether the electrode assembly 10 has an insulation defect by comparing the measured values with preset reference values. In some embodiments, the measurement device 120 may include an ammeter and a voltmeter.

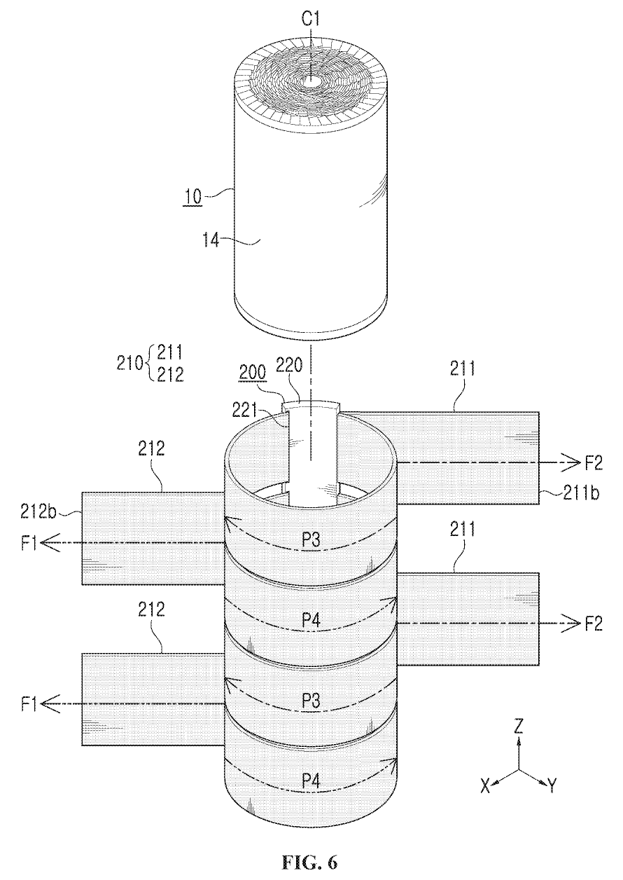

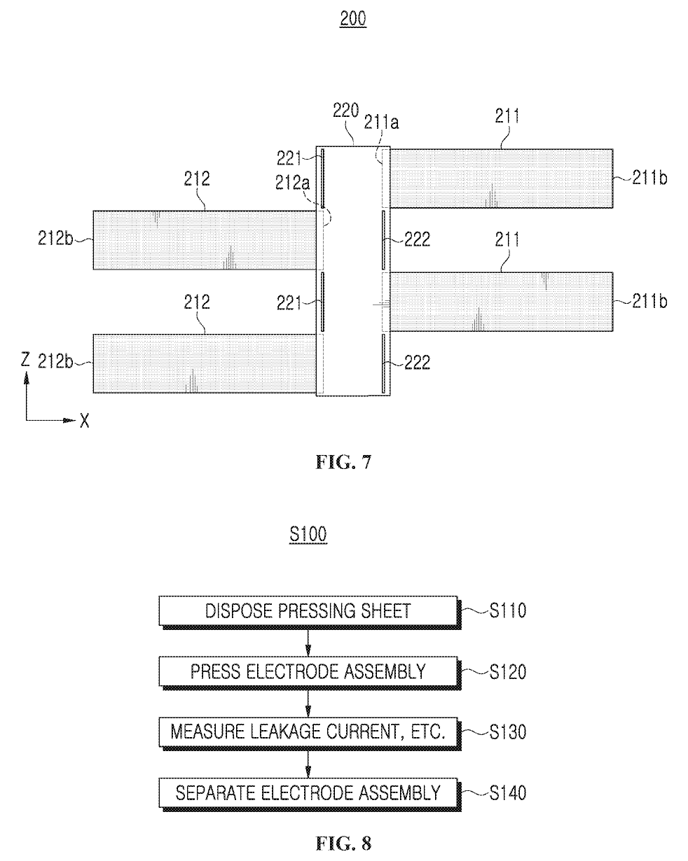

FIG. 6 is a schematic perspective view showing a test apparatus according to another embodiment of the present disclosure. FIG. 7 is a development view of the test apparatus shown in FIG. 6.

For convenience, the following description will focus on the differences from the aforementioned embodiment.

Referring to FIGS. 6 and 7, in some embodiments, a pressing sheet 210 may be divided into a plurality of parts. That is, the pressing sheet 210 may include at least one first pressing sheet 211 and at least one second pressing sheet 212. In the shown embodiment, two first pressing sheets 211 and two second pressing sheets 212 are provided. However, the number of first and second pressing sheets 211 and 212 may vary as needed and is not necessarily limited to the illustrated example. For example, each of the first and second pressing sheets 211 and 212 may be one or three or more in number. In addition, depending on the case, the first and second pressing sheets 211 and 212 may be provided in different quantities.

In some embodiments, the first pressing sheet 211 may be configured to wrap around the outer circumferential surface 14 of the electrode assembly 10 in a first rotational direction P3. Here, the first rotational direction P3 may refer to a rotational direction P3 on one side centered on the central axis C1 of the electrode assembly 10. In the shown embodiment, the first rotational direction P3 corresponds to a clockwise direction centered on the central axis C1. The first pressing sheet 211 may be configured to wrap around a part of the outer circumferential surface 14 in this manner. In the shown embodiment, the two first pressing sheets 211 are configured such that the upper first pressing sheet 211 wraps around an upper portion of the outer circumferential surface 14 and the lower first pressing sheet 211 wraps around a part of a middle portion of the outer circumferential surface 14.

In some embodiments, the second pressing sheet 212 may be configured to wrap around the outer circumferential surface 14 of the electrode assembly 10 in a second rotational direction P4. Here, the second rotational direction P4 may be a direction opposite the first rotational direction P3. That is, in the shown embodiment, the second rotational direction P4 corresponds to a counterclockwise rotation centered on the central axis C1. The second pressing sheet 212 may be configured to wrap around the remaining part of the outer circumferential surface 14 in this manner. In the shown embodiment, two second pressing sheets 212 are configured such that the upper second pressing sheet 212 wraps around the remaining part of the middle portion of the outer circumferential surface 14 and the lower second pressing sheet 212 wraps around a lower portion of the outer circumferential surface 14.

In some embodiments, each of the first and second pressing sheets 211 and 212 may be provided in plural, and the pluralities of first and second pressing sheets 211 and 212 may be alternately and repeatedly disposed in the height direction of the electrode assembly 10. That is, focusing on the shown embodiment, the first and second pressing sheets 211 and 212 may be alternately and repeatedly disposed such that the first pressing sheet 211 may be disposed in an upper region of the electrode assembly 10, the second pressing sheet 212 may be disposed thereunder, and the first pressing sheet 211 may be disposed thereunder. In some embodiments, the first and second pressing sheets 211 and 212 may be provided in the same quantity.

In some embodiments, external forces F1 and F2 may be applied to the first pressing sheet 211 and the second pressing sheet 212 in different directions. Specifically, the external force F2 may be applied to the first pressing sheet 211 in a direction corresponding to the first rotational direction P3. That is, in the shown embodiment, the first pressing sheet 211 may be configured to wrap around the outer circumferential surface 14 of the electrode assembly 10 in the clockwise direction, and the external force F2 may be applied to an end of the first pressing sheet 211 in the rightward direction in the figure. In addition, the external force F1 may be applied to the second pressing sheet 212 in a direction corresponding to the second rotational direction P4. That is, in the shown embodiment, the second pressing sheet 212 may be configured to wrap around the outer circumferential surface 14 of the electrode assembly 10 in the counterclockwise direction, and the external force F1 may be applied to an end of the second pressing sheet 212 in the leftward direction in the figure.

Accordingly, each of the first and second pressing sheets 211 and 212 may press a part of the outer circumferential surface 14 of the electrode assembly 10 corresponding thereto. In addition, the first and second pressing sheets 211 and 212 may be combined in one or more sets such that the entire outer circumferential surface 14 of the electrode assembly 10 is pressed. For example, the first and second pressing sheets 211 and 212 may be combined in two sets, as shown, to press the entire outer circumferential surface 14 of the electrode assembly 10.

In some embodiments, each of the first and second pressing sheets 211 and 212 may have a predetermined width. For reference, in the shown embodiment, the width may refer to the width of each of the first and second pressing sheets 211 and 212 in the z-axis direction. In some embodiments, the widths of the first and second pressing sheets 211 and 212 may be equal. The first and second pressing sheets 211 and 212 having the same width may apply uniform external force to the entire outer circumferential surface 14 of the electrode assembly 10. In addition, the first and second pressing sheets 211 and 212 may be disposed adjacent to each other in the width direction. That is, in the shown embodiment, a lower end of the first pressing sheet 211 in the z-axis direction may be disposed adjacent to an upper end of the second pressing sheet 212. In some embodiments, in order to reduce the region on the outer circumferential surface 14 of the electrode assembly 10 to which no pressing force is applied, the distance between the first and second pressing sheets 211 and 212 in the width direction may be minimized.

Meanwhile, in some embodiments, the test apparatus 100 may include a bracket 220 configured to support the first and second pressing sheets 211 and 212. A first end 211a of the first pressing sheet 211 in the longitudinal direction may be supported so as to be fixed to the bracket 220, and external force F2 for pressing the electrode assembly 10 may be applied to a second end 211b of the first pressing sheet 211 opposite the first end 211a. Similarly, a first end 212a of the second pressing sheet 212 in the longitudinal direction may be supported so as to be fixed to the bracket 220, and external force F1 for pressing the electrode assembly 10 may be applied to a second end 212b of the second pressing sheet 212 opposite the first end 212a.

In some embodiments, the bracket 220 may be provided with a first slit 221 configured to allow the second end 211b of the first pressing sheet 211 to be inserted thereinto and fastened thereto so as to be movable in the longitudinal direction. The first slit 221 may have a predetermined width corresponding to the first pressing sheet 211 and may be formed through the bracket 220. In some embodiments, the first slit 221 may be provided in plural so as to correspond to the number of first pressing sheets 211. Similarly, the bracket 220 may be provided with a second slit 222 configured to allow the second end 212b of the second pressing sheet 212 to be inserted thereinto and fastened thereto so as to be movable in the longitudinal direction. The second slit 222 may have a predetermined width corresponding to the second pressing sheet 212 and may be formed through the bracket 220. In some embodiments, the second slit 222 may be provided in plural so as to correspond to the number of second pressing sheets 212.

In some embodiments, the bracket 220 may include an electrically insulating material. For example, the bracket 220 may be made partially or entirely of a synthetic resin.

The first and second pressing sheets 211 and 212 may be operated to press the outer circumferential surface 14 of the electrode assembly 10 similarly to the previous embodiment. That is, external forces F1 and F2 may be applied respectively to the first and second pressing sheets 211 and 212 in different directions in the state in which the electrode assembly 10 is disposed in the mounting space. Accordingly, the first and second pressing sheets 211 and 212 may press the electrode assembly 10 to a predetermined extent in tight contact with the outer circumferential surface 14 of the electrode assembly 10. Furthermore, in the state in which the electrode assembly 10 is pressed in this manner, the measurement device may measure leakage current, etc. to determine whether the electrode assembly 10 has an insulation defect.

FIG. 8 is a flowchart showing a test method according to an embodiment of the present disclosure.

FIG. 8 illustrates a method of testing whether a secondary battery is defective using any one of the test apparatuses 100 and 200 according to the previous embodiments. The illustrated test method may be performed similarly by the test apparatus 100 described with reference to FIG. 2 and associated figures or the test apparatus 200 described with reference to FIG. 6 and associated figures. For convenience, the test method will be described hereinafter focusing on the test apparatus 100 described with reference to FIG. 2 and associated figures.

Referring to FIG. 8, in some embodiments, a secondary battery test method (hereinafter referred to as a “test method (S100)”) may be provided. In some embodiments, the test method (S100) may include a step (S110) of disposing the pressing sheet 110, provided as a flexible sheet, on an outer circumferential surface 14 of an electrode assembly 10, a step (S120) of applying external force to the pressing sheet 110 such that the pressing sheet 110 presses the outer circumferential surface 14 in tight surface contact with the outer circumferential surface 14, and a step (S130) of measuring at least one of leakage current and insulation resistance of the electrode assembly 10 in the pressed state.

Specifically, first, the pressing sheet 110 may be disposed on the outer circumferential surface 14 of the electrode assembly 10 (S110). Referring to FIG. 2, the pressing sheet 110 is disposed in the state in which the mounting space 111 is formed, and the electrode assembly 10 may be introduced into the mounting space 111. In some embodiments, to facilitate smooth introduction of the electrode assembly 10, the pressing sheet 110 may be prepared with the mounting space 111 expanded to a predetermined extent. In addition, upon introduction into the mounting space 111, the pressing sheet 110 may be disposed adjacent to the outer circumferential surface 14 of the electrode assembly 10.

Subsequently, external forces F1 and F2 may be applied to the pressing sheet 110 (S120). For example, as shown in FIG. 2, the external forces F1 and F2 may be applied to the first and second ends 110a and 110b of the pressing sheet 110 in opposite directions. Accordingly, the pressing sheet 110 may approach the outer circumferential surface 14 of the electrode assembly 10 while pressing the outer circumferential surface 14 to a predetermined extent. Here, the pressing sheet 110 may press the outer circumferential surface 14 in uniform surface contact with the entire outer circumferential surface 14 of the electrode assembly 10.

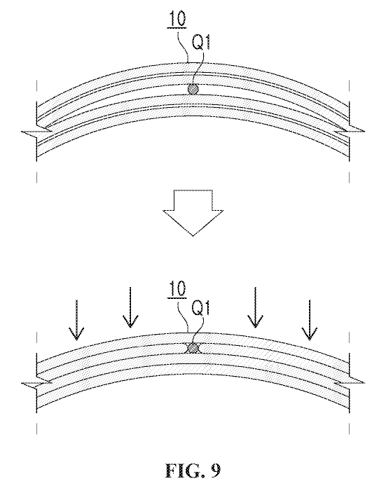

FIG. 9 is a schematic view showing the state of an electrode assembly according to a pressing step in FIG. 8.

Referring to FIG. 9, the process of pressing the electrode assembly 10 enables more reliable detection of foreign matter Q1 remaining in the electrode assembly 10. For example, as shown, the foreign matter Q1 remaining in the electrode assembly 10 has limited influence on the electrode or the separator before pressing. However, after pressing, the influence on the electrode or the separator, such as damage to the electrode or the separator, is amplified, whereby the foreign matter may be appropriately detected through the measurement of leakage current or insulation resistance in the pressed state. Accordingly, the test method (S100) may more clearly determine whether the secondary battery has processing defects.

Referring back to FIG. 8, subsequently, leakage current or insulation resistance of the electrode assembly 10 may be measured (S130). As described above, the measurement of leakage current, etc., may be performed in the state in which the electrode assembly 10 is pressed, thereby enabling clearer determination of whether the secondary battery has processing defects.

Meanwhile, in some embodiments, the test method (S100) may further include a step (S140) of separating the electrode assembly 10 from the pressing sheet 110. Specifically, upon completion of the measurement step (S130), the external forces F1 and F2 applied to the pressing sheet 110 may be released. Accordingly, the pressure exerted by the pressing sheet 110 on the electrode assembly 10 may be released, and the electrode assembly 10 may be separated from the pressing sheet 110. Depending on the case, for smooth separation of the electrode assembly 10, the pressing sheet 110 may move a predetermined distance in the opposite direction of the external forces F1 and F2 such that the mounting space 111 can expand to a predetermined extent. Once the pressure is released in this manner, the electrode assembly 10 may be separated from the pressing sheet 110. In addition, another electrode assembly 10 may be introduced for testing.

As is apparent from the above description, some embodiments of the present disclosure may provide a secondary battery test apparatus and method.

In addition, some embodiments of the present disclosure may provide a secondary battery test apparatus and method capable of appropriately determining whether a secondary battery has processing defects. In some embodiments, the test apparatus may be configured to press an outer circumferential surface of an electrode assembly in tight surface contact with the outer circumferential surface, and therefore leakage current of the electrode assembly may be measured in the state in which the influence of internal foreign matter is appropriately amplified. Accordingly, it is possible to more clearly determine whether the secondary battery has processing defects.

In addition, some embodiments of the present disclosure may provide a secondary battery test apparatus and method capable of being appropriately utilized for cylindrical electrode assemblies. In some embodiments, a pressing sheet is provided as a flexible sheet and may be configured to press the outer circumferential surface of the electrode assembly according to external force acting in the longitudinal direction. Accordingly, the test apparatus, etc. may create an appropriate pressed state for the cylindrical electrode assembly and measure leakage current, etc. Furthermore, the pressing sheet provided as a flexible sheet may be relatively easily applied to various specifications of the electrode assembly, thereby contributing to improving the usability of the test apparatus, etc.

In addition, some embodiments of the present disclosure may provide a secondary battery test apparatus and method capable of improving the reliability of test results. In some embodiments, the pressing sheet provided as a flexible sheet may uniformly apply constant pressure to the entire outer circumferential surface of the electrode assembly, and leakage current, etc. may be measured in the electrode assembly is uniformly pressed in this manner. Accordingly, the presence of internal foreign matter across the entirety of the electrode assembly may be more clearly detected, whereby the reliability of test results may be improved.

The above description is merely an example applying the principles of the present disclosure, and other configurations may be further included without departing from the scope of the present disclosure.

What is claimed is:

1. A secondary battery test apparatus comprising:
a pressing sheet disposed on an outer circumferential surface of an electrode assembly, wherein
the pressing sheet is provided as a flexible sheet configured to wrap around the outer circumferential surface, and is configured to press the outer circumferential surface toward a central axis of the electrode assembly in tight surface contact with the outer circumferential surface according to external force acting in a longitudinal direction.

2. The secondary battery test apparatus according to claim 1, wherein the electrode assembly is configured such that positive electrodes and negative electrodes alternately and repeatedly disposed with separators interposed therebetween are wound around the central axis in a cylindrical shape.

3. The secondary battery test apparatus according to claim 1, comprising a measurement device configured to measure at least one of leakage current and insulation resistance of the electrode assembly in a state in which the pressing sheet appropriately presses the outer circumferential surface.

4. The secondary battery test apparatus according to claim 1, wherein the pressing sheet comprises an electrically insulating material.

5. The secondary battery test apparatus according to claim 1, wherein the pressing sheet comprises:
a first sheet region extending from a first end thereof in the longitudinal direction; and
a second sheet region extending from an end of the first sheet region to a second end corresponding to the first end in the longitudinal direction.

6. The secondary battery test apparatus according to claim 5, wherein
the first sheet region comprises at least one slit, and
the second sheet region is inserted into and fastened to the slit so as to be movable in the longitudinal direction.

7. The secondary battery test apparatus according to claim 5, wherein
the first sheet region has a first width, and
the second sheet region has a second width less than the first width.

8. The secondary battery test apparatus according to claim 7, wherein the second width is equal to or greater to a predetermined extent than a height of the electrode assembly.

9. The secondary battery test apparatus according to claim 1, wherein the pressing sheet is configured such that external force is applied to a first end thereof in a first direction and external force is applied to a second end thereof corresponding to the first end in a second direction opposite the first direction to press the outer circumferential surface.

10. The secondary battery test apparatus according to claim 1, wherein the pressing sheet comprises:
a first pressing sheet configured to wrap around a part of the outer circumferential surface in a first rotational direction; and
a second pressing sheet configured to wrap around another part of the outer circumferential surface in a second rotational direction opposite the first rotational direction.

11. The secondary battery test apparatus according to claim 10, wherein
each of the first and second pressing sheets is provided in plural, and
the pluralities of first and second pressing sheets are alternately and repeatedly disposed in a height direction of the electrode assembly.

12. The secondary battery test apparatus according to claim 10, wherein
external force is applied to the first pressing sheet in a direction corresponding to the first rotational direction such that the first pressing sheet presses the part of the outer circumferential surface, and
external force is applied to the second pressing sheet in a direction corresponding to the second rotational direction such that the second pressing sheet presses the other part of the outer circumferential surface.

13. The secondary battery test apparatus according to claim 10, comprising:
a bracket configured to support a first end of each of the first and second pressing sheets, wherein
the bracket comprises:
a first slit configured to allow a second end of the first pressing sheet to be inserted thereinto and fastened thereto so as to be movable in the longitudinal direction; and
a second slit configured to allow a second end of the second pressing sheet to be inserted thereinto and fastened thereto so as to be movable in the longitudinal direction.

14. A secondary battery test method comprising:
disposing a pressing sheet provided as a flexible sheet on an outer circumferential surface of an electrode assembly;
applying external force to the pressing sheet such that the pressing sheet presses the outer circumferential surface in tight surface contact with the outer circumferential surface; and
measuring at least one of leakage current and insulation resistance of the electrode assembly in the pressed state.

15. The secondary battery test method according to claim 14, comprising releasing the external force and separating the electrode assembly from the pressing sheet upon completion of the measurement step.
